(19) United States
(12) Patent Application Publication
(10) Pub. No.: US 2016/0209273 A1
(43) Pub. Date: Jul. 21, 2016

(54) INFRARED RADIATION DETECTION ELEMENT, INFRARED RADIATION DETECTION DEVICE, AND PIEZOELECTRIC ELEMENT

(71) Applicant: PANASONIC INTELLECTUAL PROPERTY MANAGEMENT CO., LTD., Osaka (JP)

(72) Inventors: TAKASHI KUBO, Hyogo (JP); TOSHINARI NODA, Osaka (JP)

(21) Appl. No.: 15/023,416

(22) PCT Filed: Oct. 28, 2014
(86) PCT No.: PCT/JP2014/005433

§ 371 Date: Mar. 21, 2016

(30) Foreign Application Priority Data
Nov. 14, 2013 (JP) 2013-235669

(51) Int. Cl. G01J 5/08; H01L 41/18; G01J 5/58

(52) U.S. Cl. CPC G01J 5/0853; G01J 5/58; H01L 41/18

(57) ABSTRACT

An infrared detecting element includes a detection laminate body including a lower electrode layer, a detection layer provided on the lower electrode layer, and, an upper electrode layer provided on the detection layer. The detection layer has a columnar crystal structure. The detection layer has plural pores therein unevenly distributed mainly on a crystal grain boundary of the crystal structure. This infrared detecting element has high infrared detection performance.

### TECHNICAL FIELD

The present invention relates to an infrared detecting element, infrared detector, and piezoelectric element.

### BACKGROUND ART

Two types of infrared detecting elements: a Quantum type infrared detecting element and a thermal infrared detecting element are known. The quantum type infrared detecting element has high sensitivity and high response speed since it captures infrared rays as a band gap of semiconductor. However, the quantum type infrared detecting element needs to be cooled to a temperature of liquid nitrogen for use. A cooling unit thus needs to be provided, resulting in a large and expensive element. In addition, the quantum infrared detecting element has wavelength selectivity and shows poor responsivity to far infrared rays.

The thermal infrared detecting element includes a pyroelectric infrared detecting element made of a pyroelectric material that generates electric charge on its surface by temperature change, a resistance bolometer infrared detecting element using a resistance bolometer material having a resistance changing in response to a temperature change, and a thermocouple (thermopile) type infrared detecting element utilizing the Seebeck effect that generates an electromotive force.

In the thermal infrared detecting element, the pyroelectric infrared detecting element has large output signals, and thus a high S/N ratio since it has low noise output. In addition, since the pyroelectric infrared detecting element can be manufactured with low cost and can also detect human body, it is broadly used for auto lighting and auto switches to reduce power consumption of apparatuses.

The pyroelectric infrared detecting element utilizes the pyroelectric effect of ferroelectric material. A ferroelectric layer has a temperature increasing upon receiving infrared rays, and a surface charge on the ferroelectric layer changes by a change of polarizability in line with this temperature change. An infrared detector detects infrared rays by extracting this change in surface charge as an output signal of the infrared detecting element.

To increase the infrared reception sensitivity, a temperature rise relative to the incident infrared energy is increased. This may be achieved by making the ferroelectric layer thinner than the light-receiving area of the ferroelectric layer, using a substrate with high thermal capacity, or adopting a structure with small contact area of the substrate and the ferroelectric layer.

As a pyroelectric material of the pyroelectric infrared detecting element, pyroelectric coefficient γ is preferably high and relative permittivity εᵣ is low. This improves infrared detection performance.

FIG. 10 is a front sectional view of conventional infrared detecting element 500 disclosed in PTL1. Infrared detecting element 500 includes porous ferroelectric ceramic layer 32 having a porosity not less than 20%, dense ferroelectric ceramic layers 33 sandwiching ferroelectric ceramics 32, and electrodes 34 coupled to dense ferroelectric ceramic layers 33. Ferroelectric ceramic layers 32 and 33 are formed by processing a green sheet from slurry of ceramic particles of lead titanate (PT) or piezoelectric zirconate titanate (PZT) with relatively high pyroelectric coefficient, and then sintering the green sheet.

Porous ferroelectric ceramics 32 with high porosity is provided at the center. Pores 31 cause relative permittivity εᵣ of infrared detecting element 500 to be smaller than that of an infrared detecting element including dense ferroelectric ceramic layers 33 having the same volume as porous ferroelectric ceramics 32, thereby improving infrared detection performance.

A ferroelectric material, such as piezoelectric zirconate titanate, is an oxide having a perovskite structure expressed by general formula, ABO₃. This material has ferroelectric, piezoelectric, and electro-optic characteristics in addition to preferable pyroelectricity. The piezoelectric element made of such ferroelectric material is employed in piezoelectric sensors and piezoelectric actuators, utilizing this piezoelectric effect.

The ferroelectric material has spontaneous polarization inside, and has a positive charge and a negative charge produced on a surface thereof. In a steady state in the atmosphere, the surface is in a neutral state by being coupled with electric charges of molecules in the atmosphere. When external pressure is applied to the ferroelectric material, a surface electric charge produced on the surface by the ferroelectric material changes in response to the amount of external pressure. The piezoelectric sensor extracts this change in surface electric charge as an electric signal to detect a pressure applied to the ferroelectric material or a displacement of ferroelectric material.

The sensitivity of piezoelectric sensor can be improved by increasing piezoelectric output constant (piezoelectric g constant) Cd/εᵣ expressed by piezoelectric constant (piezoelectric d constant) Cd of piezoelectric element and relative permittivity εᵣ.

Furthermore, when a voltage is applied to the ferroelectric material, the ferroelectric material expands and contracts in response to the voltage, and causes a displacement in expanding and contracting directions or directions perpendicular to the expanding and contracting directions. A piezoelectric actuator can displace a target object using this displacement.

### CITATION LIST

### Patent Literature

PTL1: Japanese Patent Laid-Open Publication No. 8-62038

### SUMMARY

An infrared detecting element includes a detection laminate body including a lower electrode layer, a detection layer provided on the lower electrode layer, and, an upper electrode layer provided on the detection layer. The detection layer has a columnar crystal structure. The detection layer has plural pores therein unevenly distributed mainly on a crystal grain boundary of the crystal structure.

This infrared detecting element has high infrared detection performance.

### BRIEF DESCRIPTION OF DRAWINGS

FIG. 1 is a schematic top view of an infrared detecting element in accordance with an exemplary embodiment.

FIG. 2A is a schematic sectional view of the infrared detecting element on line IIA-IIA shown in FIG. 1.

FIG. 2B is a schematic sectional view of the infrared detecting element on line IIB-IIB shown in FIG. 1.

FIG. 2C is a schematic sectional view of the infrared detecting element on line IIC-IIC shown in FIG. 1.

FIG. 3 is a photo of a cross-section surface of a detection layer of the infrared detecting element taken by a transmission electron microscope in accordance with the embodiment.

FIG. 4 is a schematic view of the detection layer shown in FIG. 3.

FIG. 5 is an X-ray diffraction pattern of the detection layer of an example of the infrared detecting element in accordance with the embodiment.

FIG. 6 is an X-ray diffraction pattern of the detection layer of an example of the infrared detecting element in accordance with the embodiment.

FIG. 7 is a block diagram of an infrared detector in accordance with the embodiment.

FIG. 8 is a schematic sectional view of another infrared detecting element in accordance with the embodiment.

FIG. 9 is a schematic sectional view of a piezoelectric element in accordance with the embodiment.

FIG. 10 is a front sectional view of a conventional infrared detecting element.

### DETAIL DESCRIPTION OF PREFERRED EMBODIMENTS

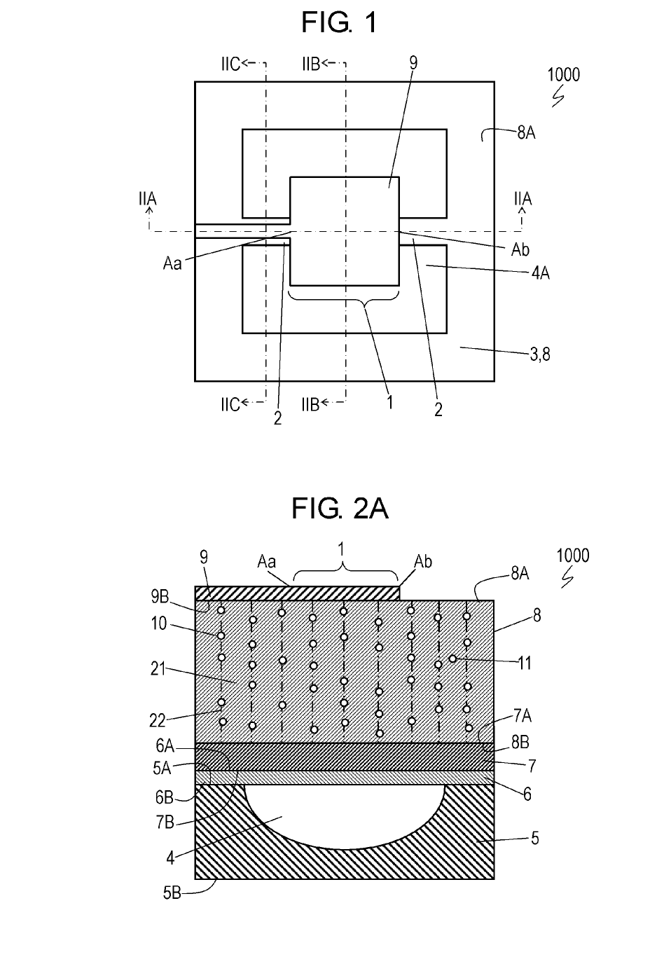

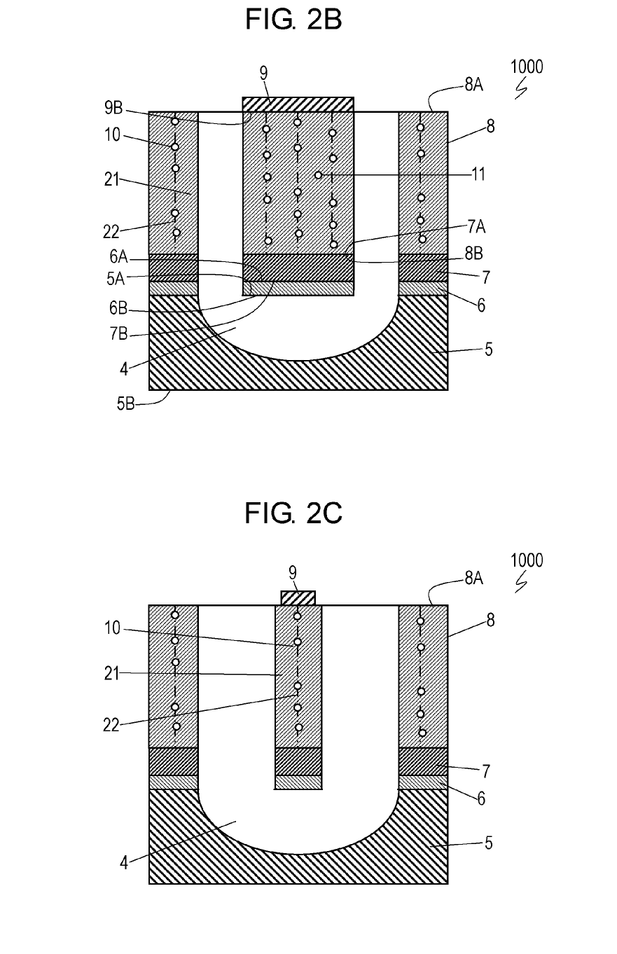

FIG. 1 is a schematic top view of infrared detecting element 1000 in accordance with an exemplary embodiment. FIGS. 2A, 2B, and 2C are schematic sectional views of infrared detecting element 1000 on lines IIA-IIA, IIB-IIB, and IIC-IIC shown in FIG. 1, respectively. Positions Aa and Ab shown in FIG. 2A are identical to positions Aa and Ab shown in FIG. 1, respectively. Infrared detecting element 1000 includes detection laminate body 1, substrate 5, and beam 2. Beam 2 is coupled to substrate 5 to hold detection laminate body 1.

Detection laminate body 1 includes lower electrode layer 7, detection layer 8 provided on upper surface 7A of lower electrode layer 7, and upper electrode layer 9 provided on upper surface 8A of detection layer 8. Lower surface 8B of detection layer 8 is located on upper surface 7A of lower electrode layer 7.

Substrate 5 has upper surface 5A which is a main surface and lower surface 5B which is another main surface. Cavity 4 is provided in upper surface 5A of substrate 5. Cavity 4 has opening 4A which opens to upper surface 5A of substrate 5. Frame 3 is provided on upper surface 5A of substrate 5 around opening 4A of cavity 4.

Cavity 4 may be provided at the center of upper surface 5A of substrate 5, but the position is not limited. Cavity 4 may communicate with lower surface 5B of substrate 5 and open to lower surface 5B of substrate 5. The shape of a section of cavity 4 may be a dome, triangle, polygonal, or trapezoidal shape.

Detection laminate body 1 is provided in opening 4A of cavity 4. Detection laminate body 1 is coupled to a part of frame 3 via beam 2 to be supported separately from the surface of substrate 5 surrounding cavity 4. Accordingly, detection laminate body 1 has high thermal insulation to substrate 5.

In infrared detecting element 1000 in accordance with the embodiment, detection laminate body 1 includes intermediate layer 6. Intermediate layer 6 is provided on upper surface 5A of substrate 5. In other words, lower surface 6B of intermediate layer 6 is located on upper surface 5A of substrate 5. Intermediate layer 6 extends substantially in parallel to upper surface 5A of substrate 5 to configure beam 2 and a part of detection laminate body 1. Lower electrode layer 7 of detection laminate body 1 is provided on upper surface 6A of intermediate layer 6. However, detection laminate body 1 may not necessarily include intermediate layer 6. In this case, lower electrode layer 7 is located on upper surface 5A of substrate 5.

Detection layer 8 is formed on upper surface 7A of lower electrode layer 7, and is made of piezoelectric zirconate titanate (PZT) oriented in a tetragonal (0001) plane. As described above, detection layer 8 is a crystal selectively oriented in a (001) direction which is a polarization axis direction, hence increasing pyroelectric coefficient γ.

In the composition of the PZT, the molar ratio Zr/Ti of Zr to Ti that is the composition of tetragonal system may preferably about 30/70. However, as long as the molar ratio Zr/Ti ranges from 0/100 to 70/30, the composition in the vicinity of a phase boundary (morphotropic phase boundary) of tetragonal system and rhombohedral system (molar ratio Zr/Ti is 53/47) and the use of PbTiO₃ are acceptable.

For constituent materials of detection layer 8, ferroelectric of perovskite-type oxide composed mainly of PZT can be used. This includes those composed mainly of PZT but a part of PZT element is replaced with, e.g. La, Ca, Sr, Nb, Mg, Mn, Zn, or Al.

Alternative constituent materials of detection layer 8 are Pb (Mg_{1/3}Nb_{2/3})O₃ (PMN) and Pb(Zn_{1/3}N_{2/3})O₃ (PZN).

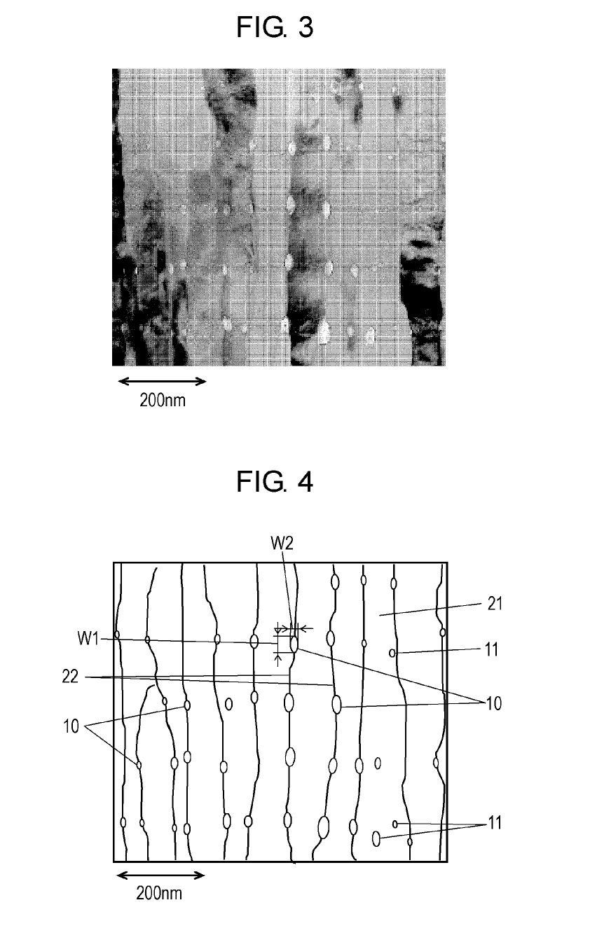

FIG. 3 is a photo of a cross-sectional surface of the detection layer of Example of the infrared detecting element described later, taken by a transmission electron microscope (TEM). FIG. 4 is a schematic view of the TEM photo shown in FIG. 3.

As shown in FIGS. 2A and 4, detection layer 8 has a columnar crystal structure. Columnar crystal 21 extends in a longitudinal direction connecting between lower electrode layer 7 and upper electrode layer 9. Crystal grain boundaries 22 exist between columnar crystals 21 and extend in the longitudinal direction.

Pores 10 and 11 are provided in detection layer 8. Pores 10 and 11 include grain-boundary pores 10 formed on crystal grain boundaries 22. Grain-boundary pores 10 are formed on at least one crystal grain boundary 22 in crystal grain boundaries 22 extending in the longitudinal direction. However, a single grain-boundary pore may be provided on crystal grain boundary 22.

On the other hand, no pores exist in crystal 21. Alternatively, a smaller amount of pores may exist in crystal 21 than grain-boundary pores 10. Crystal pores 11 may be formed in crystal 21. Crystal pores 11 are formed randomly in detection layer 8.

As shown in FIG. 3, pores formed in detection layer 8 are confirmed as a contrast in white based on observation of a photo of a cross-sectional surface of the crystal taken by a TEM.

Grain-boundary pore 10 is a pore that is at least partly observed in an area of crystal grain boundary 22. Crystal pore 11 is located away from crystal grain boundary 22, and thus, is entirely surrounded by single crystal 21.

In detection layer 8, pores 10 and 11 are unevenly distributed mainly on crystal grain boundary 22.

Uneven distribution of pores mainly on crystal grain boundary 22 means that the number of grain-boundary pores 10 provided on detection layer 8 is larger than the number of crystal pores 11 provided in detection layer 8. In other words, an uneven distribution rate of grain-boundary pores 10 which is the ratio of the number of grain-boundary pores 10 to a sum of the number of grain-boundary pores 10 and crystal pores 11 exceeds 50%.

The number of grain-boundary pores 10 and the number of crystal pores 11 in detection layer 8 can be calculated from the ratio of the number of the grain boundary pores in a predetermined region of detection layer 8 and the number of the crystal pores in the predetermined region of detection layer 8. The predetermined region can be selected appropriately depending on required calculation accuracy. For example, cross sections of the crystals at constant intervals parallel to the longitudinal direction in detection layer 8 may be selected as the predetermined region. More specifically, cross sections of the crystals at constant intervals of 20 nm near the center of detection layer 8 may be used as the predetermined region.

The pores in detection layer 8 can reduce relative permittivity εᵣ of detection layer 8. Uneven distribution of pores 10 and 11 of detection layer 8 mainly on crystal grain boundary 22 can increase pyroelectric coefficient γ since crystallinity of detection layer 8 is not deteriorated. Accordingly, infrared detecting element 1000 in accordance with the embodiment can reduce relative permittivity εᵣ and increase pyroelectric coefficient γ, and thus, providing high infrared detection performance.

In conventional infrared detecting element 500 shown in FIG. 10, relative permittivity εᵣ of ferroelectric material decreases and pyroelectric coefficient γ also drastically decreases, thus not providing sufficient infrared detection performance.

The uneven distribution rate of grain-boundary pores 10 is preferably not less than 60%. This uneven distribution rate in this range can increase pyroelectric coefficient γ. In addition, the uneven distribution rate of grain-boundary pores 10 is more preferably not less than 70%. The rate in this range can further increase pyroelectric coefficient γ.

Grain-boundary pores 10 include a lot of flat pores having substantially oval cross sections each having diameter W1 in a direction along crystal grain boundary 22 and diameter W2 in a direction perpendicular to crystal grain boundary 22. Diameter W1 is longer than diameter W2.

Diameter W1 of grain-boundary pore 10 ranges preferably from 5 nm to 50 nm on average. If diameter W1 is less than 5 nm, diameters of pores 10 can hardly controlled. This may result in unreliable reduction of relative permittivity εᵣ. If diameter W1 exceeds 50 nm, a crack tends to occur in the columnar crystal structure typically due to high-temperature environment or vibration.

Grain-boundary pores 10 and crystal pores 11 are closed pores. Closed pores can hardly absorb moisture, and suppresses deterioration in moisture resistance of detection layer 8, accordingly providing the infrared detecting element with high reliability in high humidity environment.

Substrate 5 may be made of a material with a linear thermal expansion coefficient larger than detection layer 8. More specifically, substrate 8 may be made of stainless steel composed mainly of iron or chrome.

As stainless steel used as a material of substrate 5, for example, SUS430 may be used. In this case, the linear thermal expansion coefficient of SUS430 is 10.5 ppm/K. Since the linear thermal expansion coefficient of PZT is 7.9 ppm/K, substrate 5 has a larger linear thermal expansion coefficient than detection layer 8.

In a film-forming process of detection layer 8 in a method of manufacturing infrared detecting element 1000 in accordance with the embodiment, an annealing process is necessary for forming the film. Since substrate 5 has a larger linear thermal expansion coefficient than detection layer 8, a stress remains in substrate 5 due to a difference in the linear thermal expansion coefficients by cooling detection layer 8 from a high temperature to a room temperature after re-arraying crystals of PZT of detection layer 8 at high temperature in the annealing process. A stress in a compressing direction along upper surface 5A of substrate 5 that compresses detection layer 8 is applied to the PZT in detection layer 8.

The compression stress in the direction along upper surface 5A of substrate 5 can thus be applied to detection layer 8 by thermal stress generated in the process of forming detection layer 8. This compression stress selectively orients detection layer 8 in the (001) direction, which is a polarization axis, and provides high pyroelectric coefficient γ. In other words, the polarization axis of detection layer 8 is selectively oriented in the longitudinal direction.

As the material of substrate 5 having the linear thermal expansion coefficient larger than that of detection layer 8, for example, metal materials including titanium, aluminum, or magnesium; single-crystal materials including magnesium oxide or calcium fluoride; glass materials including borosilicate glass; or ceramic materials including titanic oxide or zirconium oxide can be used besides stainless steel.

Intermediate layer 6 may be made of a material composed mainly of silicon oxide. In addition, a silicon nitride (SiON) film made by nitriding silicon oxide may be used for intermediate layer 6. Intermediate layer 6 is preferably made of an oxide material that does not have a crystal grain boundary.

Iron and chromium, which are main constituents of stainless steel for substrate 5, may be diffused in intermediate layer 6.

Iron and chromium diffused in intermediate layer 6 have the concentration gradient decreasing from substrate 5 to lower electrode layer 7. In other words, intermediate layer 6 has a region in which the concentration of materials (iron and chromium) of substrate 5 decreases in a direction from lower surface 6B to upper surface 6A.

Chromium more likely diffuses than iron, and thus diffuses more up to an upper part (upper surface 6A) of intermediate layer 6. In addition, iron has a linear thermal expansion coefficient larger than that of chromium. Accordingly, intermediate layer 6 has a region where the linear thermal expansion coefficient is larger at the side of substrate 5 due to a larger proportion of iron, i.e., near lower surface 6B, and then, the linear thermal expansion coefficient decreases toward lower electrode layer 7, i.e., upper surface 6A. This suppresses warpage of substrate 5 due to a thermal stress caused by a difference in linear thermal expansion coefficients between substrate 5 and intermediate layer 6. This suppresses deterioration in crystallinity and characteristics of lower electrode layer 7 and detection layer 8. In addition, warpage or destruction of detection laminate body 1 or beam 2 can be suppressed.

As described above, at least two kinds of elements contained in substrate 5 are diffused in intermediate layer 6. In the case that elements other than iron and chromium are diffused from substrate 5 to intermediate layer 6, the elements are selected based on the linear thermal expansion coefficients and diffusibility, as described above. In other words, an element with a larger linear thermal expansion coefficient and a higher diffusibility, and contrarily, an element with a low linear thermal expansion coefficient and a low diffusibility may be diffused in intermediate layer 6, providing the same effect.

Lower electrode layer 7 is made of a material composed mainly of nickel acid lanthanum (LaNiO₃, hereafter referred to as “LNO”). Detection layer 8 is formed on upper surface 7A of lower electrode layer 7.

LNO of lower electrode layer 7 has a space group of Ric, a perovskite structure of distorted rhombohedral system (rhombohedral system: a0=5.45 Å, a0=ap, α=60°; pseudo-cubic crystal system: a0=3.84 Å), and a resistance rate at room temperature of 1×10⁻³ (Ω·cm). LNO of lower electrode layer 7 is an oxide with metallic electric conductivity, and has a characteristic not to exhibit a transition from metal to insulation due to a temperature change.

Materials composed mainly of LNO include materials in which a part of nickel is replaced with a further other metal. The further metal contains at least one type of metal selected from a group of iron, aluminum, manganese, and cobalt. For example, this material may be LaNiO₃—LaFeO, LaNiO₃—LaAlO₃, LaNiO₃—LaMnO₃, or LaNiO₃—LaCoO₃. As necessary, Ni may be replaced with two or more types of metal in the material.

Lower electrode layer 7 functions as an orientation control layer for detection layer 8 by matching a single lattice of LNO in lower electrode layer 7 and a single lattice of PZT in detection layer 8.

In general, in this lattice matching for lattice consistency, a force to match a crystal lattice of crystal surface and a crystal lattice of film formed on the crystal surface when one crystal surface is exposed on the surface. This facilitates formation of epitaxial crystal nucleus on a boundary surface.

A lattice constant difference represents a difference between a lattice constant on a main orientation plan of LNO in lower electrode layer 7 and a lattice constant of one of (001) plane and (100) plane of PZT in detection layer 8. Orientation in one of the (001) plane and the (100) plane of PZT in detection layer 8 may increase if a ratio of the absolute value of the lattice constant difference to the absolute value of the lattice constant of detection layer 8 is within about ±10%.

A pseudo-cubic crystal structure of LNO in accordance with the embodiment has lattice constant a, where a=3.84 Å. On the other hand, cubic crystal system PZT is a material that has lattice constants a, b, and c, where a=b=4.036 Å and c=4.146 Å in a bulk ceramics value. Lower electrode layer 7 is a polycrystalline film preferentially oriented in a direction of the (100) plane.

This arrangement provides preferable lattice matching between LNO in lower electrode layer 7 and one of the (001) plane and (100) plane of PZT in detection layer 8, and PZT is generated such that it is made to orient in the (001) plane or (100) plane.

However, it is difficult to achieve selective orientation for preferentially forming a film on the (001) plane or (100) plane by orientation control using lattice matching.

In the manufacturing process of detection layer 8 in accordance with the embodiment, detection layer 8 is selectively controlled to orient in the (001) plane by applying a stress to detection layer 8 in the compressing direction. This process allows detection layer 8 to exhibit high selective orientation in the (001) direction, which is a direction of a polarization axis.

The ratio of the difference between the absolute vale of the lattice constant of the main orientation plane of LNO in lower electrode layer 7 and the lattice constant of the main orientation plane of detection layer 8 to the absolute value of the lattice constant of the (001) plane of PZT, which is the main orientation plane of this detection layer 8, is within ±10%.

The infrared detection capability of detection layer 8 is proportional to the pyroelectric coefficient of detection layer 8. A high pyroelectric coefficient is obtained by realizing a film oriented in a direction of a polarization axis of crystal.

According to the embodiment, detection layer 8 is formed on substrate 5 with large linear thermal expansion coefficient, and compression stress k due to a thermal stress is applied to detection layer 8 in the process for forming detection layer 8, so as to achieve (001) orientation, which is the polarization axis. Accordingly, detection layer 8 has high infrared detection capability.

Upper electrode layer 9 is made of nichrome (alloy of Ni and Cr) and has a thickness of 10 nm. Nichrome is conductive and has high infrared absorbency.

In addition to nichrome, any conductive material with infrared absorbency and a film thickness ranging from 5 to 500 nm may be used as a material for upper electrode layer 9. For example, conductive oxides including titanium, titanium alloy, lanthanum nickel, ruthenium oxide, and strontium ruthenate may be used as a material of upper electrode layer 9. Furthermore, metal black films including platinum black film and gold black film, in which crystal grain size of platinum or gold is controlled to give infrared absorbency, may also be used as a material of upper electrode layer 9.

A method of manufacturing the infrared detecting element in accordance with the embodiment will be described below. First, in order to form intermediate layer 6, a solution of silicon oxide precursor is applied onto substrate 5 to form a silicon oxide precursor film. Then, the silicon oxide precursor film is densified by heating to form intermediate layer 6 made of silicon oxide. Then, in order to form lower electrode layer 7, a solution of LNO precursor is applied onto intermediate layer 6 to form an LNO precursor film. Then, the LNO precursor film is crystallized by rapid heating to form lower electrode layer 7. Then, a solution of PZT precursor is applied onto lower electrode layer 7 to form a PZT precursor film. The PZT precursor film is crystallized by heating to form detection layer 8. Finally, upper electrode layer 9 is formed on detection layer 8.

Processes from a process for forming intermediate layer 6 to a process from forming upper electrode layer 9 will be detailed below.

First, a process for forming intermediate layer 6 on upper surface 5A of substrate 5 is executed. In the process for forming intermediate layer 6, a solution of silicon oxide precursor is first applied onto upper surface 5A of substrate 5 by spin-coating to form a silicon oxide precursor film. After that, a non-crystalized film is called as a precursor film.

The spin-coating at speed of 2500 rpm is executed for 30 seconds. Spin-coating allows a thin film to be applied with uniform film thickness over the plane by controlling the spinning speed.

As the solution of silicon oxide precursor, a solution composed mainly of tetraethoxysilane (TEOS, Si(OC₂H₅)₄) is used. However, a solution composed mainly of, e.g. methyltriethoxysilane (MTES, CH₃Si(OC₂H₅)₃) and perhydropolysilazane (PHPS, SiH₂NH) may be used.

Next, the silicon oxide precursor film is heated at 150° C. for 10 minutes to dry. Then, the film is heated at 500° C. for 10 minutes, and residual organic components are thermally decomposed, thereby densifying the film. The drying process aims to remove moisture physically adsorbed in the silicon oxide precursor film, and thus the temperature is preferably higher than 100° C. and lower than 200° C. If the silicon oxide precursor film is heated at a temperature higher than 200° C., residual organic components in the film start decomposing. This temperature range prevents moisture from remaining in the film of intermediate layer 6 manufactured.

Intermediate layer 6 is formed by repeating the processes from applying the silicon oxide precursor solution to substrate 5 to densification until a predetermined film thickness of intermediate layer 6 is obtained.

On heating the silicon oxide precursor film of intermediate layer 6 at 500° C., iron and chromium which are constituent elements of substrate 5 diffuse in intermediate layer 6. This diffusion produces a region where the linear thermal expansion coefficient gradually decreases in intermediate layer 6 from the side to substrate 5, i.e., from lower surface 6B, to the side to lower electrode layer 7, i.e., to upper surface 6A.

The silicon oxide layer, i.e., intermediate layer 6, is formed by chemical solution deposition (CSD). However, the method is not limited to CSD. As long as the silicon oxide precursor film is formed on substrate 5 and silicon oxide is densified by heating, any method is applicable.

Intermediate layer 6 preferably has a film thickness not less than 300 nm and not larger than 950 nm. If the film thickness is less than 300 nm, iron and chromium which are constitutional elements of substrate 5 may diffuse over the entire intermediate layer 6 and reach lower electrode layer 7. If iron and chromium are diffused up to lower electrode layer 7, crystallinity of LNO degrades. If the film thickness is larger than 950 nm, intermediate layer 6 may unpreferably crack.

Next, a process for forming lower electrode layer 7 on intermediate layer 6 is executed. The process for forming lower electrode layer 7 is to form an LNO layer by CSD. First, a solution of LNO precursor is applied onto upper surface 6A of intermediate layer 6 by spin-coating to form the LNO precursor film.

A parent material of the LNO precursor solution may be lanthanum nitrate hexahydrate (La(NO₃)₃.6H₂O) and nickel acetate tetrahydrate (CH₃COO)₂Ni.4H₂O), and 2-methoxyethanol and 2-aminoethanol as solvents. The LNO precursor solution is prepared using this parent material.

Next, the LNO precursor film is heated at 150° C. for 10 minutes to dry, and then heated at 350° C. for 10 minutes to thermally decompose residual organic components.

The processes from the process for applying the LNO precursor solution to intermediate layer 6 to the process of the thermal decomposition of residual organic components are repeated several times until the film thickness of lower electrode layer 7 reaches a predetermined film thickness, and then, the LNO precursor film is rapidly heated in a rapid thermal annealing (RTA) furnace for crystallization. A crystallizing condition is to heat the LNO precursor film at 700° C. for 5 minutes at a temperature rising rate of 200° C./minute.

Lower electrode layer 7 of LNO material may be formed by the vapor phase growth method, such as sputtering, and other film forming methods including the hydrothermal synthesis method.

Next, a process for forming detection layer 8 on lower electrode layer 7 is executed.

In the process for forming detection layer 8, a solution of PZT precursor is first prepared, and then, this prepared PZT precursor solution is applied onto upper surface 7A of lower electrode layer 7.

As a parent material of the PZT precursor solution, acetate (II) trihydrate (Pb(OCOCH₃)₂.3H₂O), titanium isopropoxide (Ti(OCH(CH₃)₂)₄), and zirconium normalpropoxide (Zr(OCH₂CH₂CH₃)₄) are used. They are dissolved and refluxed by adding ethanol, and weighed to molar ratio Zr/Ti of 25/75. Acetylacetone is added as a stabilizer to the PZT precursor solution for 0.5 mol to 1 mol of the total amount of metal positive ions.

In accordance with the embodiment, acetylacetone is used as the stabilizer. However, any substance that forms metal complex, including acetic anhydride and diethanolamine, can be used as the stabilizer.

The PZT precursor solution thus prepared using this parent material is applied onto upper surface 7A of lower electrode layer 7 by spin-coating. Then, the PZT precursor film applied onto lower electrode layer 7 is heated at 115° C. for 10 minutes to dry. The temperature in the drying is preferably higher than 100° C. and lower than 200° C. This is because decomposition of residual organic components in the PZT precursor solution starts at a temperature higher than 200° C.

Generation of pores 10 and 11 in detection layer 8 and control of the uneven distribution rate of pores 10 and 11 can be implemented by changing the thermal condition in a PZT calcining process and a crystallization process described below.

After decomposition of residual organic components is completed in the calcining step, the PZT is crystallized to unevenly distribute pores 10 and 11 mainly on crystal gain boundary 22.

First, in the calcining process, the PZT precursor film after the drying is calcined to thermally decompose the residual organic components. More specifically, a temperature in the calcining process is 400° C., and a degree of thermal decomposition of residual organic components is adjusted by changing the calcining time. The temperature in the calcining process is preferably higher than 380° C. and lower than 450° C. This is because the calcination at a temperature higher than 450° C. facilitates crystallization of the dried PZT precursor film. The calcining time is preferably not shorter than 10 minutes.

A crystallization temperature of PZT is determined according to molar ratio Zr/Ti. The Ti-rich composition shifts the crystallization temperature to a low temperature. Therefore, if the crystallization temperature is low, the uneven distribution rate of grain-boundary pores 10 can increase by lowering the calcining temperature.

Next, the processes for applying the PZT precursor solution to calcination are repeated several times until the film thickness of detection layer 8 reaches a predetermined film thickness. Then, crystallization occurs in the RTA furnace. The crystallization condition is to heat the PZT precursor film at 650° C. for 5 minutes at a temperature rising rate of 200° C./minute.

In accordance with the embodiment, the application and thermal decomposition are repeated several times in formation of the PZT layer with a predetermined film thickness, and then crystallization is executed. However, crystallization may be executed after every application and thermal decomposition. In other words, the processes from application to crystallization may be repeated several times.

The number of pores 10 in detection layer 8 can be controlled by manufacturing methods other than that described above. More specifically, the number of pores 10 can be controlled by changing the application condition of the PZT precursor solution to adjust the film thickness of the PZT precursor film per layer. For example, the thickness per layer of the PZT precursor film is reduced to increase the number of laminates so that the number of pores 10 can increase.

For example, if spin-coating is used as a method of adjusting the thickness of the PZT precursor film, the film thickness can be reduced by increasing the spin speed of substrate 5. If dip-coating is used, the thickness of the PZT precursor film can be reduced by slowing a lifting speed of substrate 5.

A method of applying the PZT precursor solution is not limited to spin-coating. A range of application methods including dip coating, spray coating, and roll coating may be used. A heating furnace used for crystallization annealing of detection layer 8 in accordance with the embodiment is not limited to the RTA furnace. An electric furnace and laser annealing may be used.

Next, a process for forming upper electrode layer 9 onto detection layer 8 is executed. In the process for forming upper electrode layer 9, upper electrode layer 9 made of a nichrome (alloy of Ni and Cr) material is formed using a range of film-forming methods in processes, such as vacuum deposition.

Next, Examples 1 and 2 with different uneven distribution rate of grain-boundary pores 10 and Comparative Example were produced for detection layer 8 in accordance with the embodiment. In Comparative Example, a temperature in the process for calcining detection layer 8 was 450° C. Other conditions were same as Example 1, and the same processes were used for manufacturing.

A microstructure at the center of a cross section of detection layer 8 is observed with a TEM. FIG. 3 shows a cross-section surface of detection layer 8 of Example 1.

As shown in the TEM photo shown in FIG. 3, a growth of columnar crystal is noticed in detection layer 8 made of PZT. Detection layer 8 has pores 10 and 11 therein appearing as white contrast. Uneven distribution of pores 10 and 11 in crystal grain boundary 22 can be confirmed.

The number of grain-boundary pores 10 and the number of crystal pores 11 in this detection layer 8 are counted using TEM photos of 20 longitudinally-parallel cross sections at constant intervals near the center of detection layer 8. Each TEM photo captures a square area of each crystal cross section having a side of about 1 μm.

As a result, the uneven distribution rate of grain-boundary pores 10 of Example 1 is 90%.

Grain-boundary pore 10 of Example 1 has diameter W1 in a direction along crystal grain boundary 22 longer than diameter W2 in a direction perpendicular to crystal grain boundary 22. Diameter W1 is about 20 nm.

Similarly, calculated uneven distribution rates of grain-boundary pores 10 of Example 2 and Comparative Example are 72% and 46%, respectively.

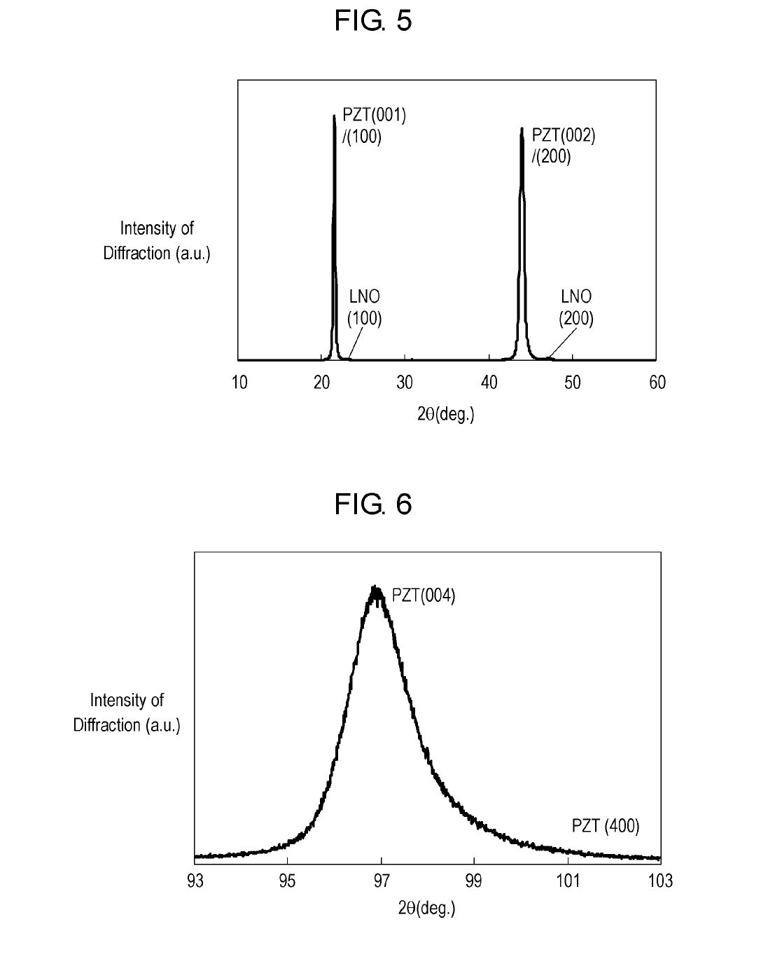

Next, crystallinity of detection layer 8 of Example 1 is evaluated using X-ray diffraction. FIG. 5 shows an X-ray diffraction pattern indicating a result of an x-ray diffraction pattern of detection layer 8 of Example 1 measured within a range of 2θ from 10° to 60°. FIG. 6 shows an X-ray diffraction pattern indicating a result of X-ray diffraction pattern of detection layer 8 of Example 1 measured in a range of 2θ from 93° to 103°.

It is apparent from FIG. 5 that detection layer 8 of Example is selectively oriented only in a direction of PZT (001)/(100). It is also apparent from FIG. 6 that peaks in the (004) plane and (400) plane are separated in detection layer 8, and the peak in the (004) plane relative to the (400) plane is large. Accordingly, it is confirmed that detection layer 8 is selectively oriented in the (004) direction, which is the polarization axis direction.

Next, electric characteristics of detection layer are measured to evaluate its infrared detection performance.

Pyroelectric coefficient γ and relative permittivity εᵣ are measured to evaluate infrared detection performance preferably based on the ratio γ/εᵣ of pyroelectric coefficient γ to relative permittivity εᵣ.

However, since the pyroelectric current is extremely too small to directly obtain pyroelectric coefficient γ practically, a pyroelectric current can be hardly measured without a precise current meter. It may thus be difficult to directly obtain pyroelectric coefficient γ.

Pyroelectric coefficient γ is a value that can be obtained from a temperature dependence of remanent polarization Pᵣ. PZT materials with substantially the same Curie temperature have pyroelectric coefficient γ increasing as remanent polarization Pᵣ increases. Remanent polarization Pᵣ can be measured more accurately than pyroelectric coefficient γ.

Therefore, the ratio Pᵣ/εᵣ of remanent polarization Pᵣ to relative permittivity εᵣ may be used for comparing infrared detection performance. For Examples 1 and 2 and Comparative Example, remanent polarization Pᵣ and relative permittivity εᵣ are thus measured and infrared detection performance is compared using ratio Pᵣ/εᵣ. Ratio Pᵣ/εᵣ is defined as an infrared detection performance index in the following description.

Table 1 shows measurement results of remanent polarization Pᵣ, relative permittivity εᵣ, and calculated infrared detection performance index (ratio Pᵣ/εᵣ).

A ferroelectric tester (precision LC) by Radiant Technology, Inc. was used for measuring remanent polarization Pᵣ. A measurement temperature was a room temperature and an applied AC voltage in measurement was 330 kV/cm.

The LCR meter (HP4284A by Hewlett-Packard Company) was used for measuring relative permittivity εᵣ, using an alternating-current (AC) voltage of 1V having a frequency of 1 kHz at a room temperature.

TABLE 1

| | Uneven | Remanent | | Infrared Detec- |
|---|---|---|---|---|
| | Distribution | Polarization | Relative | tion Perfor- |
| | Rate | Pᵣ | Permittivity | mance Index |
| | (%) | (μC/cm²) | εᵣ | (Pᵣ/εᵣ) |
| Example 1 | 90 | 40 | 350 | 0.114 |
| Example 2 | 72 | 38 | 350 | 0.109 |
| Comparative | 46 | 31 | 370 | 0.083 |
| Example | | | | |

As shown in Table 1, Example 1 exhibits remanent polarization Pᵣ of 40 μC/cm², and relative permittivity εᵣ of 350. Example 2 exhibits remanent polarization Pᵣ of 38 μC/cm² and relative permittivity εᵣ of 350. Comparative Example exhibits relatively low relative permittivity εᵣ of about 370 and remanent polarization Pᵣ lower than that of Examples 1 and 2.

It is apparent that Examples 1 and 2 have smaller relative permittivity εᵣ than Comparative Example but has larger remanent polarizations Pᵣ. In other words, Examples 1 and 2 have higher pyroelectric coefficients γ than Comparative Example. In fact, pyroelectric coefficient γ of Example 1 is about 40 nC/cm²/K and pyroelectric coefficient γ of Comparative Example is 30 nC/cm²/K.

The infrared detection performance indexes (ratio Pᵣ/εᵣ) of Example 1, Example 2, and Comparative Example are 0.114, 0.109, and 0.083, respectively. The infrared detection performance index significantly increases if the uneven distribution rate is not smaller than 70%, indicating that the infrared detection performance is improved.

As described above, the infrared detection performance can be improved by unevenly distributing pores 10 and 11 mainly on crystal grain boundary 22 to obtain high crystal orientation. On the other hand, in Comparative Example, pores are distributed substantially evenly in crystal 21 due to simultaneous progress of decomposition of residual organic components and crystallization of the detection layer. This has degraded crystallinity and small remanent polarization Pᵣ.

Next, a method of manufacturing infrared detecting element 1000 will be described below.

First, detection laminate body 1 is prepared by forming intermediate layer 6, lower electrode layer 7, detection layer 8, and upper electrode layer 9 on substrate 5 having cavity 4 which has not been yet formed, using the manufacturing method described above.

Next, upper electrode layer 9 on detection laminate body 1 is processed by photolithography. A photo resist is formed on upper electrode layer 9, and the resist is exposed with ultraviolet rays by using a chromium mask having a predetermined pattern formed thereon. Then, an unexposed portion of the resist is removed with a developer to form the predetermined pattern on the resist. Then, upper electrode layer 9 is patterned by wet etching. Other than wet etching, a range of methods, such as dry etching, can be used for patterning upper electrode layer 9.

Next, similarly to upper electrode layer 9, detection layer 8, lower electrode layer 7, and intermediate layer 6 are processed in sequence by photolithography and etching.

After processing intermediate layer 6, wet etching is applied from a portion of upper surface 5A of substrate 5 exposed from intermediate layer 6 to produce cavity 4 in substrate 5. Wet etching is performed until lower surface 6B of intermediate layer 6 formed on detection laminate body 1 and beam 2 is separated from upper surface 5A of substrate 5, thereby manufacturing infrared detecting element 1000.

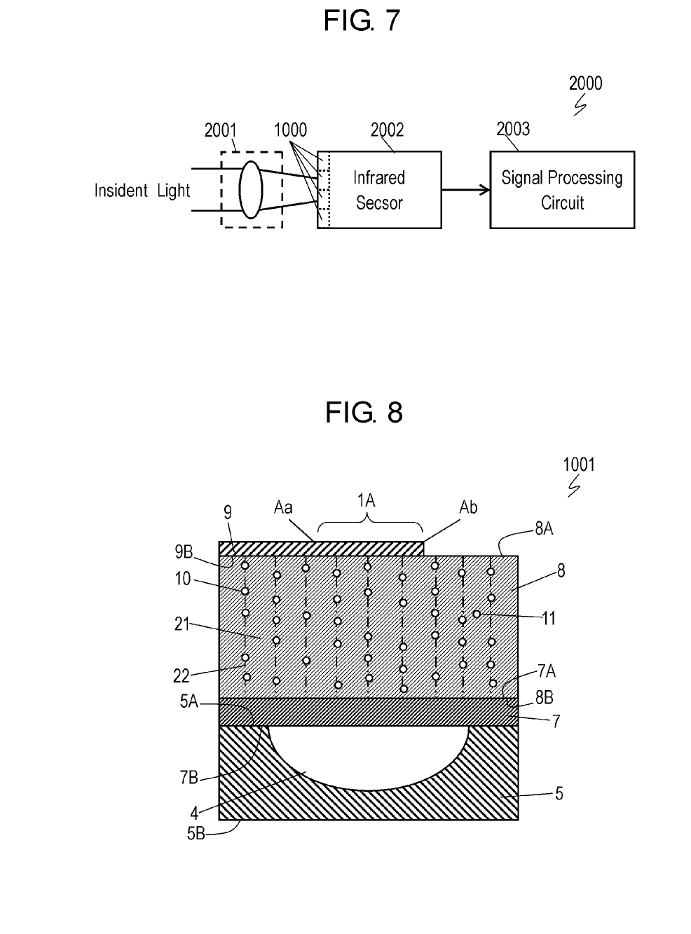

FIG. 7 is a block diagram of infrared detector 2000 in accordance with the embodiment. FIG. 7 shows an infrared detector including the infrared detecting element, and thus the infrared detector is not limited to this example.

Infrared detector 2000 includes optical system 2001, infrared sensor 2002, and signal processing circuit 2003 for processing signals output from infrared sensor 2002.

Optical system 2001 includes optical members, such as a lens for collecting incident infrared rays and a filter for selectively transmitting infrared rays. Infrared sensor 2002 receives infrared rays via optical system 2001. Infrared rays that can be used include reflected light of infrared beam irradiated to a target, such as human body, infrared beam blocked typically by movement of a target, and infrared rays discharged from human.

Infrared sensor 2002 includes single infrared detecting element 1000, or plural infrared detecting elements 1000 arranged in a two-dimensional matrix, or plural infrared detecting elements 1000 arranged on a single line. A lens array may be used in optical system 2001 corresponding to plural infrared detecting elements 1000.

An infrared sensor including single infrared detecting element 1000 or plural infrared detecting elements 1000 and optical system 2001 can be regarded as an infrared detecting element.

Signal processing circuit 2003 receives a signal output from infrared sensor 2002 (infrared detecting element 1000), and outputs a signal, such as an object detecting signal, an object transfer signal, movement signal, video signal, and temperature signal. Signal processing circuit 2003 includes active elements, such as a transistor, an FET, an IC, a logic circuit, and a semiconductor integrated circuit. These active elements typically configure an amplifying circuit that amplifies signals output from the infrared detecting element and analog digital conversion circuit.

If an incident light is modulated by, e.g. a chopper, infrared detector 2000 may use a control circuit for controlling the chopper and synchronous amplification circuit. Infrared detector 2000 may include a lamp for indicating detection of an object, a monitor typically for displaying video signals, and recording media, such as a memory for recording temperature signals.

FIG. 8 is a schematic sectional view of another infrared detecting element 1001 in accordance with the embodiment. In FIG. 8, components identical to those of infrared detecting element 1000 shown in FIGS. 1 and 2A to 2C, are denoted by the same reference numerals. Infrared detecting elements 1001 include detection laminate body 1A instead of detection laminate body 1 of infrared detecting element 1000 shown in FIGS. 1 and 2A to 2C. Detection laminate body 1A does not include intermediate layer 6. More specifically, lower surface 7B of lower electrode layer 7 is located on upper surface 5A of substrate 5 of infrared detecting element 1001. Infrared detecting element 1001 provides the same effect as uneven distribution of pores in detection layer 8 mainly on the crystal grain boundary.

As described above, detection layer 8 made of ferroelectric material has piezoelectric characteristic as well as pyroelectric characteristic. Accordingly, the structure of detection laminate body 1 of infrared detecting element 1000 in accordance with the embodiment can be used as a piezoelectric element.

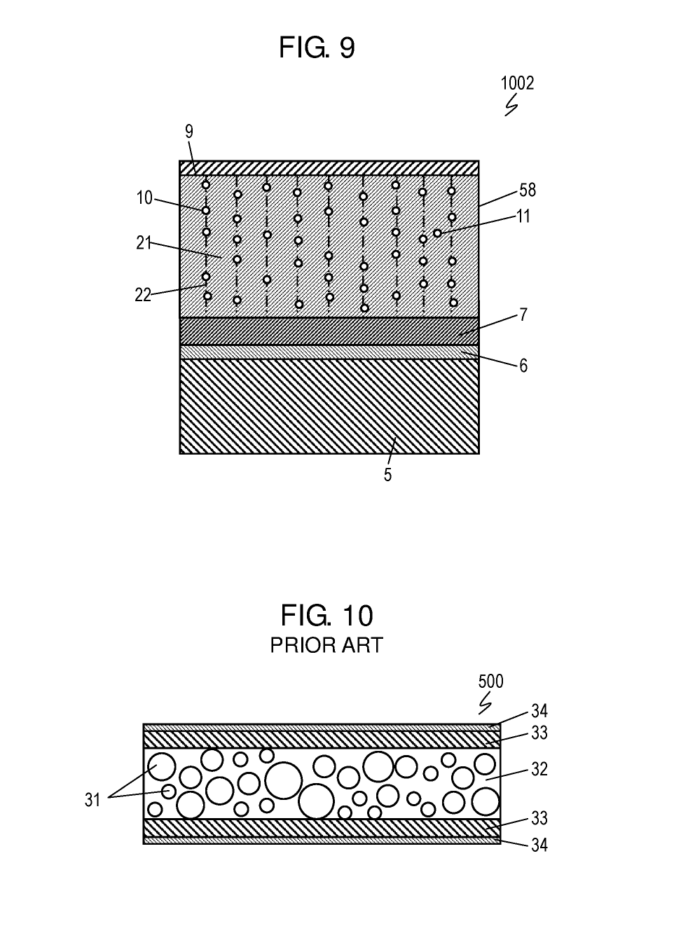

FIG. 9 is a sectional view of piezoelectric element 1002 in accordance with the embodiment. In FIG. 9, components identical to those of infrared detecting element 1000 shown in FIG. 2A are dented by the same reference numerals. Piezoelectric element 1002 has the same structure as infrared detecting element 1000 except for cavity 4 and beam 2.

The piezoelectric element includes lower electrode layer 7, piezoelectric layer 58 provided on lower electrode layer 7, and upper electrode layer 9 provided on piezoelectric layer 58.

The piezoelectric element further includes substrate 5 and intermediate layer 6 provided on substrate 5. Lower electrode layer 7 is provided on intermediate layer 6.

Piezoelectric layer 58 has a columnar crystal structure identical to that of detection layer 8 of infrared detecting element 1000 shown in FIG. 2A. In piezoelectric layer 58, pores 10 and 11 are formed and unevenly distributed mainly on crystal grain boundary 22 of the crystal structure.

As shown in FIG. 4, grain-boundary pore 10 formed on crystal grain boundary 22 has diameter W1 in a direction along crystal grain boundary 22 and diameter W2 in a direction perpendicular to crystal grain boundary 22. Diameter W1 is longer than diameter W2. The average of diameters W1 of grain-boundary pores 10 ranges from 5 nm to 50 nm.

The uneven distribution rate of grain-boundary pores 10 is preferably not less than 60%.

Piezoelectric element 1002 used for a piezoelectric sensor preferably has large ratio Cd/εᵣ of piezoelectric d constant Cd to relative permittivity εᵣ.

The piezoelectric characteristic has a positive correlation with remanent polarization Pᵣ, and thus the piezoelectric characteristic improves as remanent polarization Pᵣ increases. As shown in Table 1, Example 1 and Example 2 have larger remanent polarization Pᵣ than Comparative Example, and thus, have high piezoelectric constant. In addition, Example 1 and Example 2 have smaller relative permittivity εᵣ than Comparative Example. Accordingly, ratio Cd/εᵣ of piezoelectric d constant Cd to relative permittivity εᵣ is larger than that of Comparative Example.

As described above, the piezoelectric element in accordance with the embodiment can decrease relative permittivity εᵣ and increase piezoelectric output constant, thus providing a piezoelectric sensor and piezoelectric actuator with high conversion efficiency.

In the embodiment, terms indicating directions, such as “upper”, “lower”, “upper surface”, and “lower surface”, indicate relative directions dependent only on relative positional relationship of components, such as upper electrode layer 9, lower electrode layer 7, and detection layer 8, of infrared detecting element 1000 and piezoelectric element 1002, and do not indicate absolute directions, such as a vertical direction.

### INDUSTRIAL APPLICABILITY

An infrared detecting element according to the present invention has high infrared detection performance, and is thus effectively applicable to a range of sensors, including motion sensors and temperature sensors, and power-generating devices, including as pyroelectric power-generating devices.

Furthermore, a piezoelectric element according to the present invention has high sensitivity, and is thus effectively applicable to a range of sensors, including angular velocity sensors, and a range of actuators, including piezoelectric actuators and ultrasonic motors.

### REFERENCE MARKS IN THE DRAWINGS

1 Detection laminate body
2 Beam
4 Cavity
4A Opening
5 Substrate
6 Intermediate layer
7 Lower electrode layer
8 Detection layer
9 Upper electrode layer
10 Grain-boundary pore
11 Crystal pore
21 Crystal
22 Crystal grain boundary
58 Piezoelectric layer

1. An infrared detecting element comprising a detection laminate body including:
a lower electrode layer;
a detection layer provided on the lower electrode layer; and
an upper electrode layer provided on the detection layer,
wherein the detection layer has a columnar crystal structure, and
wherein the detection layer has a plurality of pores therein unevenly distributed mainly on a crystal grain boundary of the crystal structure.

2. The infrared detecting element of claim 1,
wherein the crystal structure includes a plurality of columnar crystals separated by the crystal grain boundary,
wherein the plurality of pores include a plurality of crystal pores provided in the plurality of columnar crystals and a plurality of grain-boundary pores provided on the crystal grain boundary, and
wherein an uneven distribution rate which is a ratio of the number of the plurality of grain-boundary pores to a sum of the number of the plurality of grain-boundary pores and the number of the plurality of crystal pores is not less than 60%.

3. The infrared detecting element of claim 1, wherein the plurality of pores include a plurality of grain-boundary pores provided on the crystal grain boundary, and a diameter of each of the plurality of grain-boundary pores in a direction along the crystal grain boundary is longer than a diameter of the each of the plurality of grain-boundary pores in a direction perpendicular to the crystal grain boundary.

4. The infrared detecting element of claim 3, wherein an average of diameters of the plurality of grain-boundary pores in the direction along the crystal grain boundary ranges from 5 nm to 50 nm.

5. The infrared detecting element of claim 1, wherein the plurality of pores are closed pores.

6. The infrared detecting element of claim 1, wherein the detection layer contains perovskite-type oxide.

7. The infrared detecting element of claim 6, wherein the detection layer is selectively oriented in a (001) plane.

8. The infrared detecting element of claim 6, wherein the detection layer mainly contains PZT, and a molar ratio of Zr to Ti in the PZT of the detection layer ranges from 0/100 to 70/30.

9. The infrared detecting element of claim 6,
wherein the lower electrode layer contains perovskite-type oxide having conductivity, and
wherein a ratio of a difference between a lattice constant of a main orientation plane of the lower electrode layer and a lattice constant of a main orientation plane of the detection layer to the lattice constant of the main orientation plane of the detection layer is within ±10%.

10. The infrared detecting element of claim 1, further comprising:
a substrate having a cavity provided therein, the cavity having an opening; and
a beam coupling the detection laminate body to the substrate,
wherein the detection laminate body is provided in the opening of the cavity in the substrate.

11. The infrared detecting element of claim 10, wherein a linear thermal expansion coefficient of the substrate is larger than a linear thermal expansion coefficient of the detection layer.

12. The infrared detecting element of claim 10, further comprising
an intermediate layer having a first surface provided on the substrate and a second surface opposite to the first surface,
wherein the lower electrode layer is provided on the second surface of the intermediate layer, and
wherein a linear thermal coefficient of the intermediate layer at each of positions in the intermediate layer decreases as the positions in the intermediate layer are located from the first surface toward the second surface.

13. An infrared detector comprising:
the infrared detecting element of claim 1; and
a signal processing circuit for processing an output signal of the infrared detecting element.

14. A piezoelectric element comprising:
a lower electrode layer;
a piezoelectric layer provided on the lower electrode layer; and
an upper electrode layer provided on the piezoelectric layer,
wherein the piezoelectric layer has a columnar crystal structure, and
wherein the piezoelectric layer has a plurality of pores therein unevenly distributed mainly on a crystal grain boundary of the crystal structure.

15. The piezoelectric element of claim 14,
wherein the crystal structure has a plurality of columnar crystals separated by the crystal grain boundary,
wherein the plurality of pores include a plurality of crystal pores provided in the plurality of columnar crystals and a plurality of grain-boundary pores provided on the crystal grain boundary, and
wherein an uneven distribution rate which is a ratio of the number of the plurality of grain-boundary pores to a sum of the number of the plurality of grain-boundary pores and the number of the plurality of crystal pores is not less than 60%.

16. The piezoelectric element of claim 14, wherein the plurality of pores include a plurality of grain-boundary pores in the crystal grain boundary, and a diameter of each of the plurality of grain-boundary pores in a direction along the crystal grain boundary is longer than a diameter of the each of the plurality of grain-boundary pores in a direction perpendicular to the crystal grain boundary.

17. The piezoelectric element of claim 16, wherein an average of diameters of the plurality of grain-boundary pores in the direction along the crystal grain boundary ranges from 5 nm to 50 nm.
